(19) United States
(12) Patent Application Publication
(10) Pub. No.: US 2011/0101480 A1
(43) Pub. Date: May 5, 2011

(54) COMPACT CAMERA MODULE AND METHOD FOR FABRICATING THE SAME

(76) Inventor: Chuan-Hui Yang, Tainan County (TW)

(21) Appl. No.: 12/611,925

(22) Filed: Nov. 3, 2009

(51) Int. Cl. H01L 31/02; H01L 21/50

(52) U.S. Cl. 257/432; 438/65; 257/433; 257/E31.11; 257/E21.499

(57) ABSTRACT

A compact camera module (CCM) includes an image sensor, a lens unit and a specific filter glass unit. The image sensor is used for sensing an image. The lens unit is used for guiding light beams toward the image sensor. The specific filter glass unit is implemented external to the lens unit and has the image sensor and the lens unit disposed on opposite sides of the specific filter glass unit, for filtering out a specific light of the light beams.

### BACKGROUND OF THE INVENTION

1. Field of the Invention

The present invention relates to a compact camera module (CCM), and more particularly, to a CCM with external filter glass and method for fabricating the same.

2. Description of the Prior Art

With the advent of technology, all kinds of portable electronic instruments and devices have become available. Product components continuously evolve towards lightweight, thin, short, and small devices. How to make an electronic product user-friendly, serve multiple functions, compact in size with ergonomic design that is not only convenient but also fashionable are major topics in the consumer market nowadays. A few examples of significant breakthrough in technological development are mobile phones that come with the function of a digital camera, or a notebook/personal digital assistant (PDA) that also works as a digital camera. All mobile phones on the current market stress compactness. Camera-type mobile phones are particularly popular. Now mobile phones can incorporate 3G functions that allow video communication between caller and recipient via the Internet. Thus the trend of the future for mobile phone is set to be diverse and full functions, and might replace traditional camera modules by utilizing a compact camera module (CCM).

Due to these trends, the development of the CCM in electronic devices tends to minimize the size and manufacturing cost of the CCM. In a prior art CCM fabricating method, a lens unit and an image sensor are fabricated individually, and then assembled by housing the image sensor into the lens unit or bonding the lens unit onto the wafer level image sensor. The lens unit is usually composed of a barrel, lens, spacer, aperture stop and infrared radiation (IR) filter glass. The above-mentioned components implemented in the lens unit need to be fabricated precisely, so that the quality of the lens unit can remain constant. However, the manufacturing cost of the CCM will inevitably be increased.

### SUMMARY OF THE INVENTION

It is therefore one of the objectives of the present invention to provide a CCM and a method for fabricating the same, that decreases the manufacturing cost typically associated with CCMs.

According to an embodiment of the present invention, an exemplary CCM is disclosed. The exemplary CCM includes an image sensor, a lens unit and a specific filter glass unit. The image sensor is used for sensing an image. The lens unit is used for guiding light beams toward the image sensor. The specific filter glass unit, external to the lens unit and having the image sensor and the lens unit disposed on opposite sides of the specific filter glass unit, is used for filtering out a specific light of the light beams.

According to another embodiment of the present invention, an exemplary method for fabricating a plurality of CCMs is disclosed. The exemplary method includes: providing a plurality of image sensors formed on a wafer, a specific filter glass wafer, and a plurality of lens units; forming a bonded wafer according to the image sensors formed on the wafer, the specific filter glass wafer, and the lens units, wherein the specific filter glass wafer is disposed between the image sensors formed on the wafer and the lens units; and cutting the bonded wafer to generate the CCMs.

According to yet another embodiment of the present invention, an exemplary method for fabricating a CCM is disclosed. The exemplary method includes: providing an image sensor, a specific filter glass unit, and a lens unit; and forming the CCM according to the image sensor, the specific filter glass unit, and the lens unit, wherein the specific filter glass unit is disposed between the image sensor and the lens unit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a compact camera module (CCM) according to an exemplary embodiment of the present invention.

FIG. 2 is a side view of a CCM according to another exemplary embodiment of the present invention.

FIG. 3 is a perspective view of a bonded wafer according to an exemplary embodiment of the present invention.

FIG. 4 is a flowchart illustrating a method for fabricating a plurality of CCMs according to an exemplary embodiment of the present invention.

FIG. 5 is a flowchart illustrating a method for fabricating a CCM according to an exemplary embodiment of the present invention.

### DETAILED DESCRIPTION

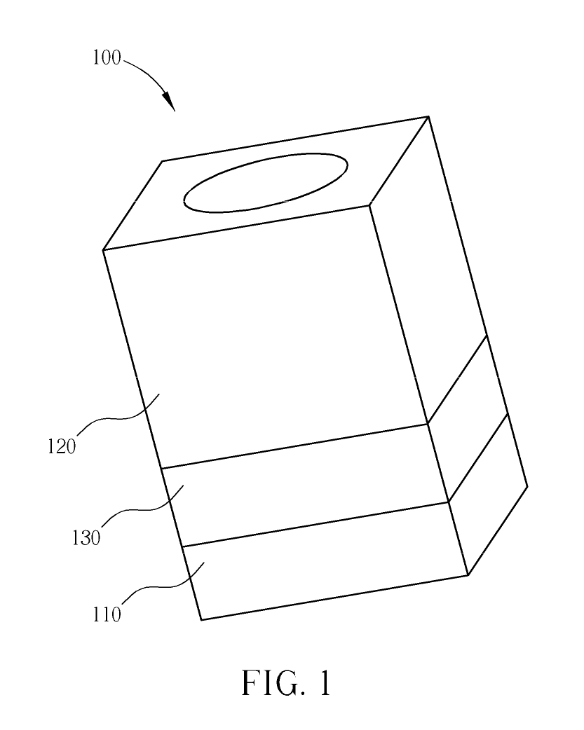

Please refer to FIG. 1. FIG. 1 is a diagram illustrating a compact camera module (CCM) according to an exemplary embodiment of the present invention. In this embodiment, the CCM 100 includes, but is not limited to, an image sensor 110, a lens unit 120 and an infrared radiation (IR) filter glass unit 130. The image sensor 110 is used for sensing an image. The lens unit 120 is used for guiding light beams toward the image sensor 110. The IR filter glass unit 130 is used for filtering out IR light of the light beams. Please note that the IR filter glass unit 130 is a filter glass which can filter out an IR light of the light beams in this exemplary embodiment; however, this is for illustrative purposes only, and is by no means a limitation to the scope of the present invention. Using another filter glass to realize the desired filter glass unit which can filter out other unwanted light components of the light beams also falls within the scope of the present invention.

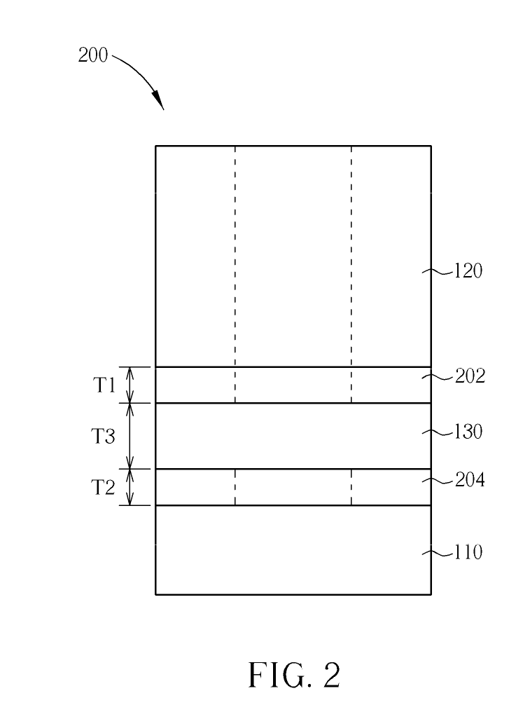

The image sensor 110 and the IR filter glass unit 130 can be connected by a spacer or an adhesive material, and the IR filter glass unit 130 and the lens unit 120 can also be connected by a spacer or an adhesive material. Please refer to FIG. 2, which is a side view of a CCM according to another exemplary embodiment of the present invention. As can be seen from FIG. 2, the CCM 200 includes, but is not limited to, the image sensor 110, the lens unit 120, the IR filter glass unit 130, a first optional spacer unit/adhesive material 202, and a second optional spacer unit/adhesive material 204. During the manufacturing/assembling process, a focus point of the CCM 200 can be adjusted by a thickness T1 of the first optional spacer unit/adhesive material 202, a thickness T2 of the second optional spacer unit/adhesive material 204, and/or a thickness T3 of the IR filter glass unit 130. Therefore, the focus point of the CCM 200 can be flexibly adjusted to derive an optimal focus point.

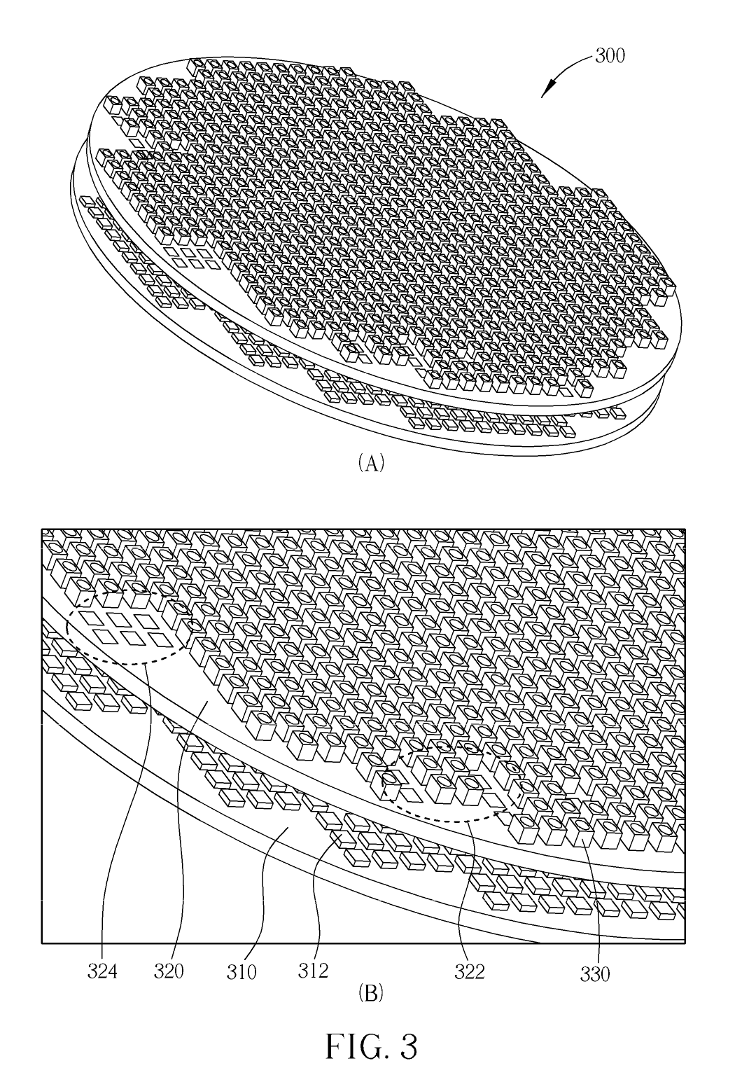

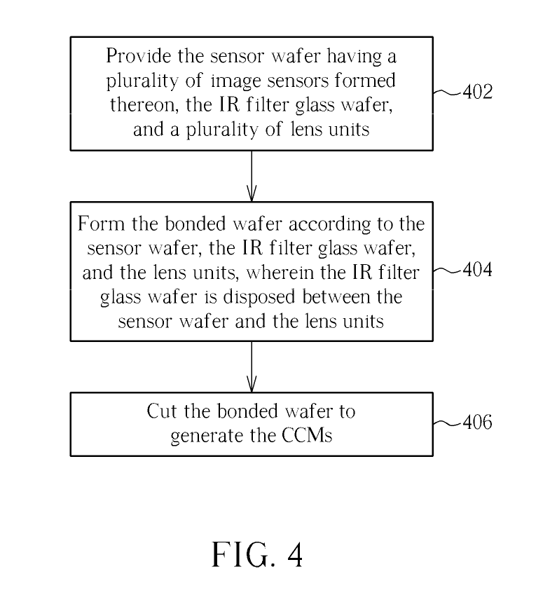

Please refer to FIG. 3. FIG. 3 is a perspective view of a bonded wafer 300 according to an exemplary embodiment of the present invention. The sub-diagram (A) in FIG. 3 is an overview of the complete bonded wafer 300, while the other sub-diagram (B) in FIG. 3 is an enlarged view of a portion of the bonded wafer 300. The bonded wafer 300 includes, but is not limited to, a sensor wafer 310 having a plurality of image sensors 312 formed thereon, an IR filter glass wafer 320, and a plurality of lens units 330. Please refer to FIG. 4 in conjunction with FIG. 3. FIG. 4 is a flowchart illustrating a method for fabricating a plurality of CCMs 100 with the bonded wafer 300 according to an exemplary embodiment of the present invention. Please note that, provided the same result is substantially achieved, the steps of the flow shown in FIG. 4 need not be in the exact order shown and need not be contiguous; that is, other steps can be intermediate. The exemplary method for fabricating the plurality of CCMs 100 includes the following steps:

Step 402: Provide the sensor wafer 310 having a plurality of image sensors 312 formed thereon, the IR filter glass wafer 320, and a plurality of lens units 330.

Step 404: Form the bonded wafer 300 according to the sensor wafer 310, the IR filter glass wafer 320, and the lens units 330, wherein the IR filter glass wafer 320 is disposed between the sensor wafer 310 and the lens units 330.

Step 406: Cut the bonded wafer 300 to generate the CCMs 100. By way of example, the lens unit 120 is one of the lens units 330, the IR filter glass unit 130 is derived from cutting the IR filter glass wafer 320, and the image sensor 110 is one image sensor 312 obtained from cutting the sensor wafer 310.

In step 404, a spacer can be disposed between the wafer 310 and the IR filter glass wafer 320 or disposed between the IR filter glass wafer 320 and the lens units 330, for adjusting focus points of the CCMs 100 by setting a thickness of the spacer. For example, the spacer unit 204 shown in FIG. 2 is derived from cutting the spacer disposed between the wafer 310 and the IR filter glass wafer 320; and the spacer unit 202 shown in FIG. 2 is derived from cutting the spacer disposed between the IR filter glass wafer 320 and the lens units 330. Additionally, the wafer 310 and the IR filter glass wafer 320 or the IR filter glass wafer 320 and the lens units 330 can be adhered by an adhesive material, for adjusting focus points of the CCMs 100 by setting a thickness of the adhesive material. The focus points of the CCMs 100 can also be adjusted by setting a thickness of the IR filter glass wafer 320. The lens units 330 can be bonded to the IR filter glass wafer 320 according to a yield map of the sensor wafer 310, to prevent bonding the lens units 330 onto the broken image sensors. As shown in sub-diagram (B) in FIG. 3, some lens units 330 are not bonded in dotted circle regions 322 and 324 of the IR filter glass wafer 320 due to the corresponded image sensors 312 formed upon the sensor wafer 310 are broken image sensors according to the yield map of the sensor wafer 310. Therefore, the manufacturing cost of the CCM 100 can be reduced greatly.

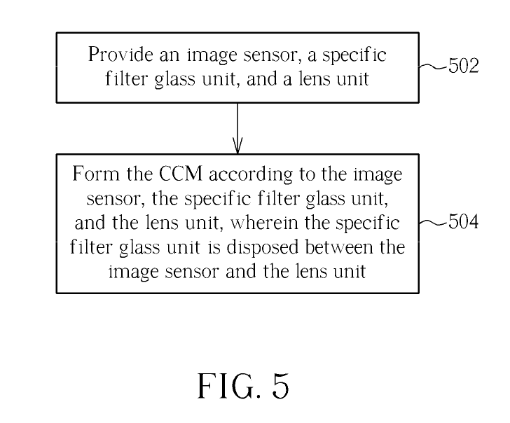

Please note that the method for fabricating the CCM 100 is not limited in the present invention. With some appropriate modifications made to the disclosed exemplary embodiments without departing from the spirit of the present invention, the CCM 100 of the present invention can also be fabricated one by one, as shown in FIG. 5. The exemplary method for fabricating a single compact camera module (CCM) includes the following steps: providing an image sensor, a specific filter glass unit, and a lens unit (step 502); and forming the CCM according to the image sensor, the specific filter glass unit, and the lens unit, wherein the specific filter glass unit is disposed between the image sensor and the lens unit (step 504). Similarly, a focus point of the CCM can be adjusted by a thickness of a spacer unit/adhesive material and/or a thickness of the IR filter glass unit, as mentioned above. These alternative designs all fall within the scope of the present invention.

In summary, the present invention provides a CCM and a method for fabricating the same. Since the filter glass unit of the CCM is external to the lens unit, the lens unit can be fabricated without executing the cutting and assembling procedures of the filter glass unit, and the lens unit can be bonded to the filter glass wafer according to a yield map of a sensor wafer. Therefore, the manufacturing cost of the CCM is decreased.

Those skilled in the art will readily observe that numerous modifications and alterations of the device and method may be made while retaining the teachings of the invention.

What is claimed is:

1. A compact camera module (CCM), comprising:
an image sensor, for sensing an image;
a lens unit, for guiding light beams toward the image sensor; and
a specific filter glass unit, external to the lens unit and having the image sensor and the lens unit disposed on opposite sides of the specific filter glass unit, for filtering out a specific light of the light beams.

2. The CCM of claim 1, further comprising:
a spacer unit, disposed between the image sensor and the specific filter glass unit.

3. The CCM of claim 1, further comprising:
a spacer unit, disposed between the specific filter glass unit and the lens unit.

4. The CCM of claim 1, further comprising:
an adhesive material, coated in between the image sensor and the specific filter glass unit.

5. The CCM of claim 1, further comprising:
an adhesive material, coated in between the specific filter glass unit and the lens unit.

6. The CCM of claim 1, wherein the specific filter glass unit is an infrared radiation (IR) filter glass unit.

7. A method for fabricating a plurality of compact camera modules (CCMs), comprising:
providing a plurality of image sensors formed on a wafer, a specific filter glass wafer, and a plurality of lens units;
forming a bonded wafer according to the image sensors formed on the wafer, the specific filter glass wafer, and the lens units, wherein the specific filter glass wafer is disposed between the image sensors formed on the wafer and the lens units; and
cutting the bonded wafer to generate the CCMs.

8. The method of claim 7, wherein the step of forming the bonded wafer further comprises:
setting a thickness of a spacer for adjusting focus points of the CCMs; and
disposing the spacer between the image sensors formed on the wafer and the specific filter glass wafer.

9. The method of claim 7, wherein the step of forming the bonded wafer further comprises:
setting a thickness of an adhesive material for adjusting focus points of the CCMs; and
adhering the image sensors formed on the wafer with the specific filter glass wafer with the adhesive material.

10. The method of claim 7, wherein the step of forming the bonded wafer further comprises:
setting a thickness of a spacer for adjusting focus points of the CCMs; and
disposing the spacer between the specific filter glass wafer and the lens units.

11. The method of claim 7, wherein the step of forming the bonded wafer further comprises:
setting a thickness of an adhesive material for adjusting focus points of the CCMs; and
adhering the lens units to the specific filter glass wafer with the adhesive material.

12. The method of claim 7, further comprising:
setting a thickness of the specific filter glass wafer for adjusting focus points of the CCMs.

13. The method of claim 7, wherein the specific filter glass wafer is an infrared radiation (IR) filter glass wafer.

14. The method of claim 7, wherein the step of forming the bonded wafer comprises:
bonding the lens units to the specific filter glass wafer according to a yield map of the image sensors formed on the wafer.

15. A method for fabricating a compact camera module (CCM), comprising:
providing an image sensor, a specific filter glass unit, and a lens unit; and
forming the CCM according to the image sensor, the specific filter glass unit, and the lens unit, wherein the specific filter glass unit is disposed between the image sensor and the lens unit.

16. The method of claim 15, wherein the step of forming the CCM further comprises:
setting a thickness of a spacer unit for adjusting a focus point of the CCM; and
disposing the spacer unit between the image sensor and the specific filter glass unit.

17. The method of claim 15, wherein the step of forming the CCM further comprises:
setting a thickness of an adhesive material for adjusting a focus point of the CCM; and
adhering the image sensor with the specific filter glass unit utilizing the adhesive material.

18. The method of claim 15, wherein the step of forming the CCM further comprises:
setting a thickness of a spacer unit for adjusting a focus point of the CCM; and
disposing the spacer unit between the specific filter glass unit and the lens unit.

19. The method of claim 15, wherein the step of forming the CCM further comprises:
setting a thickness of an adhesive material for adjusting a focus point of the CCM; and
adhering the lens unit to the specific filter glass unit utilizing the adhesive material.

20. The method of claim 15, further comprising:
setting a thickness of the specific filter glass unit for adjusting a focus point of the CCM.
